(19) United States
(12) Patent Application Publication
(10) Pub. No.: US 2025/0211114 A1
(43) Pub. Date: Jun. 26, 2025

(54) SEMICONDUCTOR DEVICE AND METHOD OF MANUFACTURING THE SAME

(71) Applicant: Renesas Electronics Corporation, Tokyo (JP)

(72) Inventor: Hideyuki TAJIMA, Tokyo (JP)

(21) Appl. No.: 18/961,673

(22) Filed: Nov. 27, 2024

(30) Foreign Application Priority Data
Dec. 25, 2023 (JP) 2023-217779

(51) Int. Cl. H02M 3/158; H02M 3/157

(52) U.S. Cl. CPC H02M 3/158; H02M 3/157

(57) ABSTRACT

A semiconductor device includes a first terminal, an oscillation circuit that generates a first clock signal and a second clock signal, an AD conversion circuit, a correction circuit that corrects the digital signal obtained by the AD conversion circuit based on a correction data stored in a memory circuit and outputs the digital signal, an averaging circuit, a sampling circuit, a current generation circuit, and a superposition circuit, the correction data is generated based on an output of the sampling circuit when a dispersion current is superposed on a detection current, and is stored in the memory circuit.

### CROSS-REFERENCE TO RELATED APPLICATIONS

The disclosure of Japanese Patent Application No. 2023-217779 filed on Dec. 25, 2023 including the specification, drawings and abstract is incorporated herein by reference in its entirety.

### BACKGROUND

The present invention relates to a semiconductor device and a method of manufacturing the semiconductor device, for example, a semiconductor device including an analog-to-digital (hereinafter also referred to as AD) conversion circuit and a method of manufacturing the same.

There are disclosed techniques listed below. [Non-Patent Document 1] AN118: Improving ADC Resolution By Oversampling and Averaging, [online], 2013 7/13, Rev. 1.3, Silicon Laboratories, P. 1-P. 20, [Searched on Nov. 9, 2023], Internet <URL: https://WWW.silabs.com/documents/public/application-note/an118.pdf>

Non-Patent Document 1 discloses a technique for improving the resolution of an AD conversion circuit, for example. In Non-Patent Document 1, it is illustrated that by sampling the analog signal at a frequency higher than the frequency determined by the sampling theorem, performing AD conversion, and averaging by a digital filter, thereby improving the apparent resolution. This allows to perform high-resolution measurements using a low-resolution AD conversion circuit, thereby reducing the cost. In the following description, sampling at a frequency higher than the frequency determined by the sampling theorem (that is, a frequency twice the maximum frequency of an analog signal) is referred to as oversampling.

### SUMMARY

As a semiconductor device including an AD conversion circuit, for example, there is a semiconductor device that converts an output signal output from the semiconductor device using the AD conversion circuit, and adjusts the value of the output signal based on the pulse width corresponding to a difference between the digital signal obtained by the AD conversion circuit and the target value data. By using an AD conversion circuit and a digital filter in accordance with the technique disclosed in Non-Patent Document 1 as the AD conversion circuit installed in such a semiconductor device, the cost of the semiconductor device can be reduced while improving the resolution.

On the other hand, an error occurs in an analog block including the AD conversion circuit. In order to reduce such an error, it is conceivable to install a digital correction circuit (hereinafter also simply referred to as a correction circuit) and a memory circuit that supplies correction data to the correction circuit on the semiconductor device. In this case, it is conceivable to, during the testing step of manufacturing the semiconductor device, input a predetermined value into the AD conversion circuit, generate correction data to correct an error occurring in the analogue block based on the digital signal (digital signal corresponding to the predetermined value) obtained by the AD conversion circuit, and write the correction data into the memory circuit. When the semiconductor device is actually in use, the correction circuit reduces the errors contained in the digital signal output from the AD conversion circuit using the correction data.

In the technique disclosed in Non-Patent Document 1, in order to achieve the effects of averaging by the digital filter, it is assumed that the signal input into the AD conversion circuit contains a certain amount of noise. Therefore, during the testing step, it is required for the predetermined value to be input into the AD conversion circuit to also contain a certain amount of noise. Accordingly, the inventors considered generating an alternating current signal using a tester or the like during the testing step and inputting the alternating current signal as the predetermined value into the AD conversion circuit. However, this approach leads to a problem of an increased testing cost.

A brief summary of a representative embodiment disclosed in the present application is as follows.

That is, a semiconductor device according to one embodiment includes a first terminal, an oscillation circuit that generates a first clock signal and a second clock signal having a frequency that is an integer fraction of the first clock signal, an AD conversion circuit that oversamples a detection current corresponding to a current flowing through the first terminal in accordance with the first clock signal and converts the detection current into a digital signal, a correction circuit that corrects the digital signal obtained by the AD conversion circuit based on a correction data stored in a memory circuit and outputs the digital signal, an averaging circuit that operates in accordance with the first clock signal and averages the digital signal output from the correction circuit, a sampling circuit that downsamples the digital signal averaged by the averaging circuit in accordance with the second clock signal, a current generation circuit that generates a current based on an output of the sampling circuit and target current data and supplies the current to the first terminal, and a superposition circuit that superposes a dispersion current on the detection current when generating the correction data. Here, the correction data is generated based on an output of the sampling circuit when the dispersion current is superposed on the detection current, and is stored in the memory circuit.

Other objects and novel features will be apparent from the description of the present specification and the accompanying drawings.

According to one embodiment, it is possible to provide a semiconductor device including an AD conversion circuit capable of improving resolution while suppressing an increase in cost.

### BRIEF DESCRIPTION OF THE DRAWINGS

FIG. 1 is a block diagram illustrating a configuration of a semiconductor device according to a first embodiment.

FIG. 2 is a set of waveform diagrams for illustrating an operation of the semiconductor device according to the first embodiment.

FIG. 3 is a block diagram for illustrating the superposition of dispersion current according to the first embodiment.

FIG. 4 is a circuit diagram illustrating an example of a DA conversion circuit according to the first embodiment.

FIG. 5 is a schematic waveform diagram for illustrating an operation during testing of the semiconductor device according to the first embodiment.

FIG. 6 is a schematic waveform diagram for illustrating an operation during testing of the semiconductor device according to the first embodiment.

FIG. 7 is a waveform diagram illustrating a comparative example according to the first embodiment.

FIG. 8A is a waveform diagram illustrating an operation during testing of the semiconductor device according to the first embodiment.

FIG. 8B is a waveform diagram illustrating an operation during testing of the semiconductor device according to the first embodiment.

FIG. 8C is a waveform diagram illustrating an operation during testing of the semiconductor device according to the first embodiment.

FIG. 8D is a waveform diagram illustrating an operation during testing of the semiconductor device according to the first embodiment.

FIG. 9 is a block diagram for illustrating a semiconductor device according to a second embodiment.

FIG. 10 is a waveform diagram illustrating an operation of the semiconductor device according to the second embodiment.

FIG. 11 is a block diagram for illustrating a semiconductor device according to a third embodiment.

FIGS. 12A and 12B are flow charts for illustrating a method of manufacturing the semiconductor device according to the first embodiment.

FIG. 13 is a schematic block diagram illustrating an example of a test board according to the first embodiment.

FIG. 14 is a block diagram for illustrating a reduction of errors occurring in analog blocks and accompanying problems.

### DETAILED DESCRIPTION

Hereinafter, embodiments of the present invention will be described with reference to the drawings. It should be noted that the disclosure is a mere example, and any modifications that can be readily conceived by a person skilled in the art without deviating from the spirit of the invention are, rightfully included within the scope of the present invention.

Also, in the present specification and the accompanying drawings, the same reference numerals are assigned to elements similar to those previously described in the preceding figures, and detailed descriptions may be omitted as appropriate.

### First Embodiment

### <Configuration of Semiconductor Device>

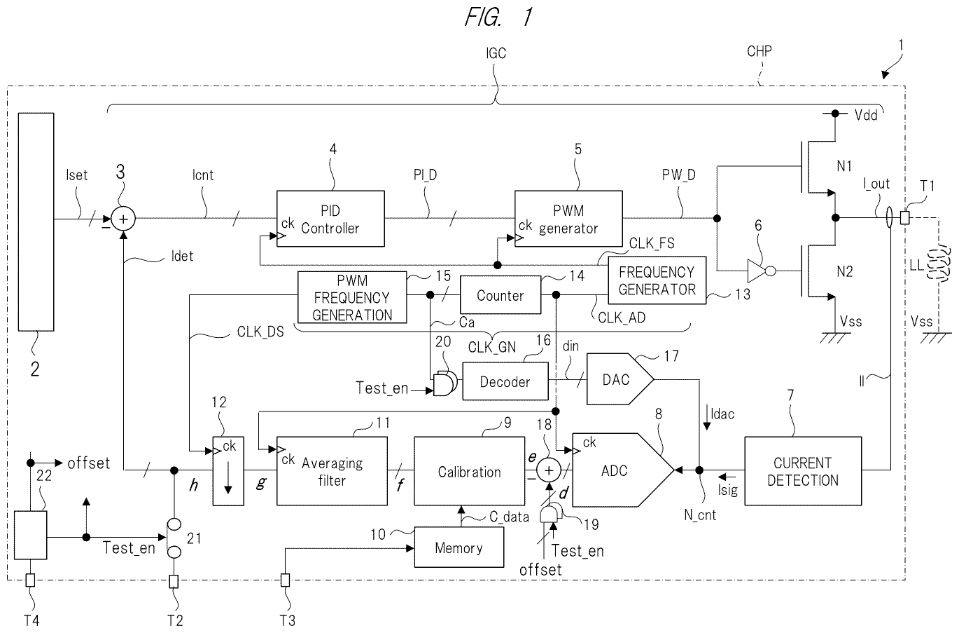

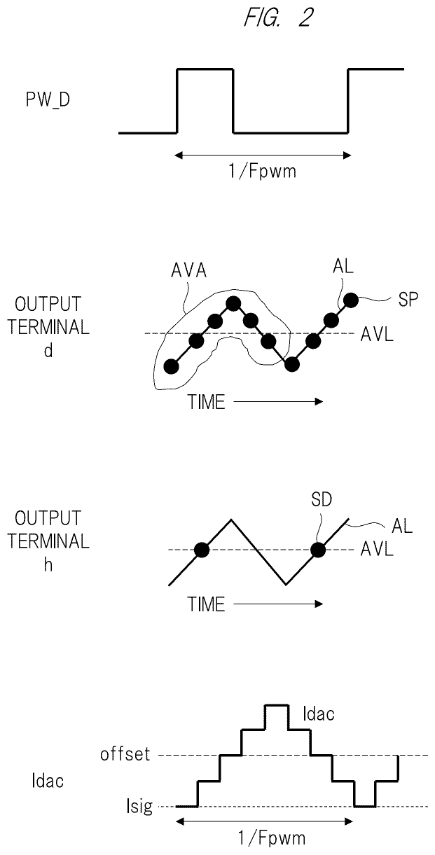

FIG. 1 is a block diagram illustrating a configuration of a semiconductor device according to a first embodiment, and FIG. 2 is a set of waveform diagrams for illustrating an operation of the semiconductor device according to the first embodiment. The semiconductor device 1 according to the first embodiment includes a single semiconductor substrate on which a plurality of circuit blocks are formed using a known semiconductor manufacturing technique, and a plurality of external terminals (hereinafter also referred to as terminals) to which the circuit blocks formed on the semiconductor substrate are connected. Although not particularly limited, the semiconductor substrate is sealed with a single package, and the plurality of external terminals protrude from the package.

In FIG. 1, a CHP enclosed by an alternate long and short dash line indicates the semiconductor substrate on which the plurality of circuit blocks are formed. Although various circuit blocks are formed as the plurality of circuit blocks on the semiconductor substrate CHP, only the circuit blocks necessary for the illustration are illustrated in FIG. 1. Also, in FIG. 1, T1 to T4 indicate the external terminals connected to the circuit blocks. As for the external terminals, similarly to the circuit blocks, only those necessary for the illustration are illustrated in FIG. 1.

In the first embodiment, a semiconductor device including a current regulator that outputs a current corresponding to a target current value (target value data) specified by a user via the external terminals will be described as an example of the semiconductor device 1. However, it is naturally not limited to this example.

In FIG. 1, the reference numeral 2 denotes a target data output circuit that outputs a target current value (digital value) Iset specified by the user. The target current value Iset is supplied to a current generation circuit IGC.

The current generation circuit IGC includes an arithmetic circuit 3, a PID control circuit 4, a PWM generation circuit 5, an inverter circuit 6, and N-channel field effect transistors N1 and N2. In the following, a field effect transistor will be referred to as a MOS transistor, an N-channel MOS transistor will be referred to as a NMOS transistor, and a P-channel MOS transistor will be referred to as a PMOS transistor.

The arithmetic circuit 3 calculates the difference between a detection current (digital value) Idet, which will be described later, and the target current value Iset, and supplies the calculated difference to the PID control circuit 4 as a control current (digital value) Icnt.

The PID control circuit 4 operates in accordance with a clock signal CLK_FS supplied to a clock terminal ck, and generates a control signal (digital value) PI_D corresponding to the input control current Icnt, and outputs thereof to the PWM generation circuit 5. The PWM generation circuit 5 also operates in accordance with the clock signal CLK_FS supplied to a clock terminal ck, generates a PWM control signal PW_D, and outputs thereof to the inverter circuit 6 and the gate of the NMOS transistor N1. The frequency of the clock signal CLK_FS is, for example, 16 MHz. The PWM control signal PW_D output by the PWM generation circuit 5 is a periodic signal with a predetermined frequency Fpwm, and the period of the PWM control signal PW_D is 1/Fpwm as illustrated in FIG. 2. By means of the PID control circuit 4 and the PWM generation circuit 5, a PWM control signal PW_D is generated in which the ratio of the high-level period to the low-level period within the period 1/Fpwm varies in accordance with the value of the control current Icnt.

The drain of the CMOS transistor N1 is connected to the supply voltage Vdd, the source of the NMOS transistor N2 is connected to the ground voltage Vss, and the source of the NMOS transistor N1 is connected to the drain of the NMOS transistor N2 and the external terminal (first terminal) T1. Also, an output of the inverter circuit 6 is supplied to the gate of the NMOS transistor N2.

Accordingly, during the high-level period of the PWM control signal PW_D, the NMOS transistor N1 is in the On state, and the NMOS transistor N2 is in the Off state, allowing a current I_out to flow between the supply voltage Vdd and the external terminal T1 via the NMOS transistor N1. On the other hand, during the low-level period of the PWM control signal PW_D, the NMOS transistor N2 is in the On state, and the NMOS transistor N1 is in the Off state, allowing the current I_out to flow between the external terminal T1 and the ground voltage Vss via the NMOS transistor N2. As a result, the current generation circuit IGC generates the current (output current) I_out based on the target current value Iset and the detection current Idet, and supplies thereof to the external terminal T1.

In the semiconductor device 1 according to the first embodiment, a correlation current (analog value) I1 correlated with the current flowing through the external terminal T1 is used to generate the detection current Idet. The correlation current I1 is detected by a current detection circuit 7 and is output from the current detection circuit 7 to an AD conversion circuit 8 as a detection current (analog value) Isig.

A clock signal CLK_AD is supplied to a clock terminal ck of the AD conversion circuit 8. The AD conversion circuit 8 samples the detection current Isig supplied to an input terminal thereof using the clock signal CLK_AD supplied to the clock terminal ck, converts the sampled signal into a digital detection signal, and outputs the detection signal from an output terminal d. In the first embodiment, although not particularly limited, the AD conversion circuit 8 is an AD conversion circuit with a resolution of 10 bits.

The sampling frequency of the AD conversion circuit 8 determined by the sampling theorem, that is, the frequency of the clock signal CLK_AD supplied to the clock terminal ck, is 125 kHz relative to the frequency of the detection current supplied to the input terminal of the AD conversion circuit 8. However, in the first embodiment, the frequency of the clock signal CLK_AD is set to 1 MHz. That is, the AD conversion circuit 8 converts the analog detection current into a digital signal by oversampling.

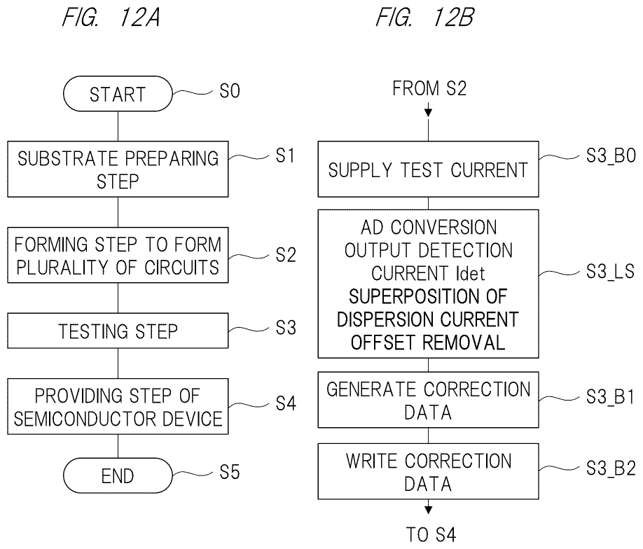

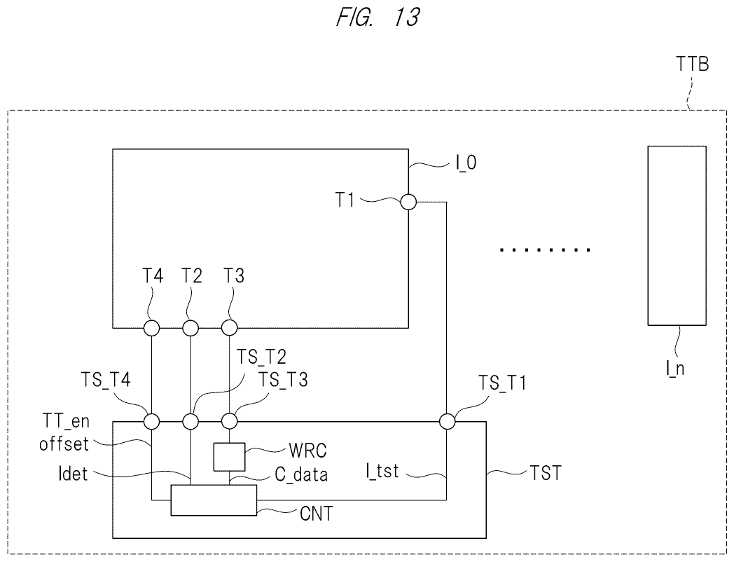

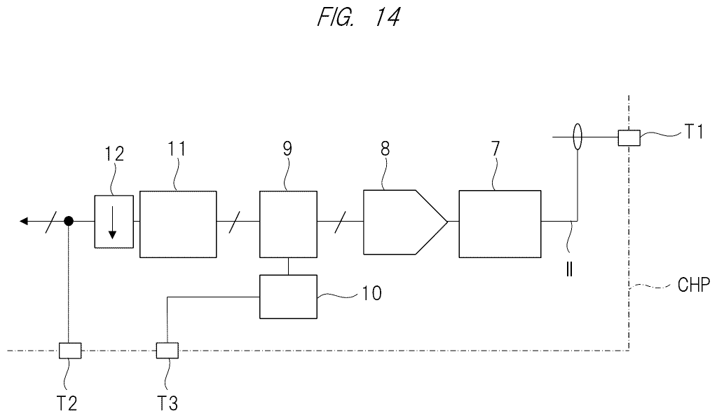

The detection signal output from the output terminal d of the AD conversion circuit 8 is supplied to an arithmetic circuit 18. An output signal of the arithmetic circuit 18 (a digital signal at an output terminal e of the arithmetic circuit 18) is supplied to a correction circuit (hereinafter also referred to as a calibration circuit) 9. As an example will be illustrated later with reference to FIG. 14, an error occurs in an analog block including the AD conversion circuit 8. In order to reduce such an error, the correction circuit 9 and a memory circuit 10 that stores correction data C_data are provided. As will be described later with reference to FIGS. 12 and 13, the correction data C_data is obtained in a testing step during manufacturing the semiconductor device 1, and is written into the memory circuit 10.

When the current generation circuit IGC generates a current corresponding to the target current value Iset and supplies the current as the output current I_out to the external terminal T1, that is, when the semiconductor device 1 actually operates as a current regulator, the correction circuit 9 corrects the output signal supplied from the arithmetic circuit 18 using the correction data C_data supplied from the memory circuit 10. An output signal (digital value) of a correction result obtained by the correction by the correction circuit 9 is supplied from an output terminal f of the correction circuit 9 to an averaging circuit 11.

The averaging circuit 11 includes a digital filter (averaging filter) that operates in accordance with the clock signal supplied to the clock terminal ck. The clock signal supplied to the clock terminal ck of the averaging circuit 11 is the same clock signal CLK_AD as the clock signal supplied to the clock terminal ck of the AD conversion circuit 8. The averaging circuit 11 averages the supplied output signal of the correction circuit 9 and outputs the averaged signal as an analog output signal from an output terminal g.

The analog output signal output from the averaging circuit 11 is supplied to a downsampling (sampling) circuit 12. The downsampling (downsampler) 12 downsamples the analog output signal supplied from the averaging circuit 11 in accordance with a clock signal CLK_DS supplied to a clock terminal ck, and outputs the downsambled signal as a digital output signal from an output terminal h. The digital output signal output from the output terminal h is supplied to the arithmetic circuit 3 as the detection current Idet.

In the first embodiment, the frequency of the clock signal CLK_DS is 125 kHz. That is, the frequency of the clock signal CLK_DS is ⅛ of the frequency of the clock signal CLK_AD, which is the sampling frequency determined by the sampling theorem.

In addition to a schematic waveform of described PWM control signal PW_D, a schematic waveform at the output terminal d of the AD conversion circuit 8 and a schematic waveform at the output terminal h of the downsampling circuit 12 are also illustrated in FIG. 2. Next, the operation of the AD conversion circuit 8 and the operation of the downsampling circuit 12 will be described with reference to the schematic waveforms at the output terminals d and h. As to the waveforms at the output terminals d and h in FIG. 2, AL indicates the waveforms (triangular waveform) of the analog signal input into the AD conversion circuit 8 and the downsampling circuit 12. Also, as to the waveform at the output terminal d, black circles (•) SP indicate the timing at which sampling is performed in the AD conversion circuit 8 (sampling timing) and values of codes (output codes) output from the AD conversion circuit 8. Further, as to the waveform at the output terminal h, black circles (•) SD indicate the sampling timing at which sampling is performed in the downsampling circuit 12 and values of output codes output from the downsampling circuit 12.

In the AD conversion circuit 8, oversampling is performed; therefore, the number of times sampling is performed within one period of the analog signal AL (averaging area) is as large as, for example, six times (the number of black circles SP). Whereas, in the downsampling circuit 12, the number of times sampling is performed within one period of the analog signal AL is as small as, for example, once (black circle SD). From a different perspective, the output codes obtained from sampling by the AD conversion circuit 8 can be considered as being thinned to fewer output codes by the downsampling circuit 12.

Further, as to the waveform at the output terminal d, the dashed line AVL indicates the average value of the six output codes (black circles SP) included in the averaging area AVA. The six output codes (black circles SP) obtained by AD conversion by the AD conversion circuit 8 are averaged by the averaging circuit 11. As a result, the output signal from the averaging circuit 11, schematically, has the form of the waveform indicated by the dashed line AVL in FIG. 2. As illustrated in the output terminal d of FIG. 2, even if the resolution is low and the black circles SP do not exist at the sampling timing for sampling the dashed line AVL, sampling of the dashed line AVL obtained by averaging can be performed at the black circle SD, as illustrated in the output terminal h of FIG. 2. That is, even if the resolution is low, the resolution can be improved by performing oversampling and averaging.

The above-described clock signals CLK_FS, CLK_AD and CLK_DS are generated by a clock generation circuit (oscillation circuit) CLK_GN. The clock generation circuit CLK_GN according to the first embodiment includes a frequency generator 13, a counter 14, and a PWM frequency generation circuit 15. The frequency generator 13 generates the clock signals CLK_FS and CLK_AD of a predetermined frequency. The clock signal (first clock signal) CLK_AD is supplied to the clock terminals ck of the AD conversion circuit 8 and the averaging circuit 11 as described above, and is also supplied to the counter 14. The counter 14 counts the pulses of the clock signal CLK_AD and supplies the count value to the PWM frequency generation circuit 15. Based on the supplied count value, the PWM frequency generation circuit 15 generates the signal (a second clock signal with a frequency that is an integer fraction of the first clock signal) CLK_DS and supplies the generated signal to the clock terminal ck of the downsampling circuit 12, as described above.

The semiconductor device 1 also includes a control circuit 22 including a control register (not illustrated), a switch 21 controlled by a test enable signal (hereinafter also simply referred to as a test signal) Test_en output from the control circuit 22, an external terminal (fourth terminal) T4 connected to the control circuit 22, an external terminal (second terminal) T2 connected to the output terminal h of the downsampling circuit 12 via the switch 21, and an external terminal (third terminal) T3 connected to the memory circuit 10.

Further, the semiconductor device 1 includes logic circuits 19 and 20, a decoder 16 connected to an output terminal ca of the counter 14 via the logic circuit 20, and a digital-to-analog (hereinafter also referred to as DA) conversion circuit 17 that converts the output signal (digital value) din of the decoder 16 into an analog value.

The control circuit 22, the switch 21, the external terminals T2 to T4, the logic circuits 19 and 20, the decoder 16, and the DA conversion circuit 17 will be described later and description thereof is omitted here.

In FIG. 1, the symbol LL indicates a schematic load connected between the external terminal T1 and the ground voltage Vss.

### <<Overview of Current Regulator Operation>>

When the semiconductor device 1 operates, the current generation circuit IGC generates an output current I_out and supplies the output current I_out from the external terminal T1 to the load LL. By the current detection circuit 7, a correlation current I1 correlated with the output current I_out is detected, and the current detection circuit 7 outputs a detection current Isig corresponding to the correlation current I1. The detection current Isig is sampled by the AD conversion circuit 8 by oversampling and converted into a digital detection signal. The digital detection signal is then corrected by the correction circuit 9 and averaged by the averaging circuit 11. The analog output signal obtained by the averaging is downsampled by the downsampling circuit 12 to generate the detection current Idet. In the current generation circuit IGC, the period during which the NMOS transistors N1 and N2 are in the On state is controlled so that the detection current Idet coincides with the target current value Iset. This process is repeated, and the output current I_out, which corresponds to the target current value Iset, is supplied from the external terminal T1 to the load LL.

### <Manufacturing of Semiconductor Device>

The semiconductor device 1 according to the first embodiment is subjected to testing in the manufacturing step before being provided to a user. Based on the detection current measured by the test, correction data is generated and written into the memory circuit 10 of the semiconductor device 1.

FIGS. 12A and 12B are flow charts for illustrating a method of manufacturing the semiconductor device according to the first embodiment. Here, FIG. 12A is a flow chart illustrating the entire manufacturing method, and FIG. 12B is a flow chart illustrating details of Step S3 in FIG. 12A.

In Step S0 illustrated in FIG. 12A, the manufacture of the semiconductor device 1 starts. Step S1 is a preparation step for preparing a semiconductor substrate. In Step S2, which is a formation step, a plurality of circuit blocks including the circuit blocks illustrated in FIG. 1 and the like are formed on the semiconductor substrate prepared in the preparation step S1 by a known semiconductor manufacturing method. In Step S2, the external terminals T1 to T4 and the like illustrated in FIG. 1 are connected to the circuit blocks, and sealed by a package to complete the semiconductor device 1.

Next, in Step S3, the test of the semiconductor device 1 is performed. The testing step in Step S3 will be described with reference to FIG. 12B, so the description thereof is omitted here. In Step S4 after Step S3, the semiconductor device 1 is provided to a user, and in Step S5, the manufacture of the semiconductor device is completed.

### <<Testing Step>>

In the testing step of Step S3, the semiconductor device 1 according to the first embodiment is mounted on a test board, where the test is performed, and correction data is written.

FIG. 13 is a schematic block diagram illustrating an example of the test board according to the first embodiment. In FIG. 13, the dashed line TTB indicates a schematic diagram of the test board. A plurality of semiconductor devices 1_0 to 1_n (each corresponding to the semiconductor device 1 in FIG. 1) completed in Step S2 are mounted on the test board TTB, and the test, generation of correction data, and writing of the correction data are performed by a tester TST. Although FIG. 13 illustrates a state in which one semiconductor device 1_0 is connected to the tester TST, the other semiconductor devices (1_n, etc.) are similarly connected.

The tester TST also includes a plurality of circuit blocks, but in FIG. 13, only the circuit blocks necessary for the illustration are illustrated. In FIG. 13, CNT indicates a control circuit, WRC indicates a writing circuit, and TS_T1 to TS_T4 indicate the external terminals of the tester TST.

During testing, the control circuit CNT generates a test current I_tst and supplies the current to the external terminal T1 of the semiconductor device 1_0 via the external terminal TS_T1. The test current I_tst is a predetermined fixed current. Also, during testing, the control circuit CNT supplies test setting data TT_en for generating a test signal Test_en and an offset value Offset, which will be described later, to the external terminal T4 of the semiconductor device 1_0 via the external terminal ST_T4. Further, during testing, the control circuit CNT is supplied with the detection current Idet via an external terminal TS_T2 connected to the external terminal T2 of the semiconductor device 1_0. The control circuit CNT generates the correction data C_data based on the test current I_tst and the detection current Idet, and supplies the correction data C_data to the writing circuit WRC. The writing circuit WRC supplies the supplied correction data C_data to the external terminal T3 of the semiconductor device 1_0 via an external terminal TS_T3.

In FIG. 12B, Steps S3_B0 to S3_B2 illustrate steps that are mainly performed by the tester TST illustrated in FIG. 13, and Step S3_LS illustrates a step that is mainly performed by the semiconductor device 1_0 (corresponding to the semiconductor device 1 in FIG. 1) illustrated in FIG. 13.

In Step S3_B0, the control circuit CNT (FIG. 13) of the tester TST stores the test setting data TT_en and the offset value Offset in a register (not illustrated) in the control circuit 22 (FIG. 1) via the external terminal T4 of the semiconductor device 1_0. As a result, the control circuit 22 generates the test signal Test_en that turns On the switch 21, and also outputs the offset value Offset. Further, the control circuit CNT generates the test current I_tst and supplies the current to the external terminal T1 (FIG. 13) of the semiconductor device 1_0. As a result, in the semiconductor device 1_0, the correlation current I1 (FIG. 1) correlated with the test current I_tst is supplied to the current detection circuit 7, and the current detection circuit 7 outputs the detection current Isig having a value corresponding to the test current I_tst.

In Step S3_LS, in the semiconductor device 1_0, the AD conversion circuit 8 (FIG. 1) converts the detection current Isig output from the current detection circuit 7 into a digital signal by oversampling. The digital detection signal obtained by the conversion (output from the output terminal d) is output via the arithmetic circuit 18, the correction circuit 9, the averaging circuit 11, and the downsampling circuit 12 as the detection current Idet corresponding to the test current I_tst. At this point, the switch 21 (FIG. 1) is in the On state, and accordingly, the detection current Idet is supplied to the control circuit CNT of the tester TST via the switch 21, the external terminal T2 of the semiconductor device 1_0, and the external terminal TS_T2 of the tester TST.

In Step S3_B1, the control circuit CNT of the tester TST generates the correction data C_data such that the supplied detection current Idet coincides with an ideal value when the test current I_tst is AD-converted, and outputs the correction data C_data to the writing circuit WRC.

Next, in Step S3_B2, the writing circuit WRC in the tester TST supplies the correction data C_data to the memory circuit 10 via the external terminal T3 of the semiconductor device 1_0, and writes the correction data C_data into the memory circuit 10.

As a result, the manufacturing of the semiconductor device 1_0, that includes the memory circuit 10 into which the correction data C_data for correcting an error occurring in the analog block including the AD conversion circuit is written, is completed, and Step S4 in FIG. 12A is executed.

<Reducing Errors Occurring in Analog blocks and Problems>

FIG. 14 is a block diagram for illustrating the reduction of errors occurring in analog blocks and accompanying problems. FIG. 14 illustrates a configuration of the semiconductor device 1_0 when Step S3_LS illustrated in FIG. 12B is being executed. FIG. 14 is similar to FIG. 1. The main difference is in that FIG. 14 illustrates only the current detection circuit 7, the AD conversion circuit 8, the correction circuit 9, the memory circuit 10, the averaging circuit 11, the downsampling circuit 12, and the external terminals T1 to T3.

In analog blocks such as the current detection circuit 7 and the AD conversion circuit 8, errors occur due to variations in manufacturing conditions and the like. The errors are corrected by the correction circuit 9 based on the correction data C_data supplied from the memory circuit 10.

To generate the correction data C_data, the tester TST supplies a predetermined fixed current as a test current I_tst to the external terminal T1 of the semiconductor device 1_0, and measures the detection current Idet output at this point from the external terminal T2 of the semiconductor device 1_0. That is, a current based on the test current I_tst, which is a predetermined fixed current with little noise, is detected by the current detection circuit 7, and the detection current Isig is oversampled and converted into a digital signal. Because there is little noise, it is considered that even if oversampling is performed, a plurality of digital values obtained thereby will be the same value (output code), and thus the averaging effect of the averaging circuit 11 may not be obtained. If the averaging effect is not achieved, the output of the downsampling circuit 12 will have the original resolution of the AD conversion circuit 8. For example, if the AD conversion circuit 8 has a resolution of 10 bits, the output of the downsampling circuit 12 will also have a precision of 10 bits.

As a countermeasure, it is possible to intentionally vary the test current I_tst. To intentionally vary the test current I_tst, for example, the control circuit CNT of the tester TST illustrated in FIG. 13 needs to generate a test current that varies at a frequency ranging from several kHz to several tens of kHz. Alternatively, when generating the correction data C_data using a mass production board on which the semiconductor device 1_0 is actually mounted, instead of the tester TST illustrated in FIG. 13, it is required to add elements (passive elements and active elements) to the mass production board in order to vary the test current I_tst. In either case, the testing cost of the semiconductor device increases, which is not practical.

As a further countermeasure, it is also conceivable to mount a high-precision (for example, higher resolution than 10-bit) AD conversion circuit in the semiconductor device. In this case, however, the occupation area occupied by the AD conversion circuit increases, and the cost of the semiconductor chip increases, which is undesirable.

### <Superposition of Dispersion Current and Offset Removal>

In the semiconductor device according to the first embodiment, a dispersion current Idac as illustrated in FIG. 2 is generated in the semiconductor device 1 during the testing step. The dispersion current Idac is a current that varies periodically with a frequency of Fpwm and a period of (1/Fpwm). As illustrated in FIG. 1, the generated dispersion current Idec is superposed onto the detection current Isig output from the current detection circuit 7 and supplied to the AD conversion circuit 8. Also, the dispersion current Idac fluctuates above and below around a value that is higher by the offset value Offset with the detection current Isig being the reference. In Step S3_LS in FIG. 12B, as illustrated in bold, the superposition of the dispersion current Idac (dispersion current superposition) and the removal of the offset value Offset (offset removal) are executed.

That is, during the testing step, the dispersion current Idac is superposed onto the detection current Isig corresponding to the test current I_tst. In other words, the dispersion current Idac, which varies periodically, is superposed onto the input of the AD conversion circuit 8 as periodic noise. As a result, the AD conversion circuit 8 converts a plurality of values obtained by oversampling into different digital values, allowing the effect of averaging by the averaging circuit to be achieved. That is, it becomes possible to achieve a resolution higher than the original resolution of the AD conversion circuit 8. As a result, a high-precision detection current Idet can be obtained via the external terminal T2 during testing, while preventing an increase in the testing cost and, further, suppressing a cost increase of a semiconductor chip. Accordingly, in the control circuit CNT of the tester TST, high-precision correction data C_data can be generated, and, during testing, the high-precision correction data C_data can be written into the memory circuit 10.

When the semiconductor device 1 is actually used, the errors in the analog blocks are corrected based on the high-precision correction data C_data, allowing for the acquisition of precise digital signals. In the example of the semiconductor device 1 illustrated in FIG. 1, it becomes possible to output an output current I_out that more accurately coincides with the target current value Iset.

Further, in the first embodiment, the digital value corresponding to the offset value Offset illustrated in FIG. 2 is subtracted from the output of the AD conversion circuit 8. Accordingly, the configuration of the AD conversion circuit 8 as well as the configuration of the circuit block that generates the dispersion current Idac can be simplified.

### <<Configuration for Generating Dispersion Current>>

Returning to FIG. 1, the configuration for generating the dispersion current will be specifically described.

The dispersion current Idac is generated by the logic circuit 20, the decoder 16, and the DA conversion circuit 17.

The logic circuit 20 is supplied with the output signal (count value) output from the output terminal ca of the counter 14 and the test signal Test_en. When the test signal Test_en indicates a test state, the logic circuit 20 becomes conductive and supplies the output signal from the counter 14 to the decoder 16. The decoder 16 decodes the supplied output signal and outputs a digital output signal din corresponding to the dispersion current Idac. In the first embodiment, the decoder 16 outputs 4-bit parallel digital signals din0 to din3 based on the output signal from the counter 14 as the output signal din, although there is no particular limitation thereto. The decoder 16 outputs an output signal din which forms a triangular waveform over one period (1/Fpwm) when converted into an analog signal, like the dispersion current Idac illustrated in FIG. 2, and this occurs as the clock signal CLK_AD supplied to counter 14 varies, causing the logic values of the digital signals din0 to din3 to vary. Naturally, the output signal din is not limited to a 4-bit digital signal.

The output signal din is converted into the analog dispersion current Idac by the DA conversion circuit 17. The output of the DA conversion circuit 17 and the output of the current detection circuit 7 are connected at a connection node (first node) N_cnt, and the detection current Isig output from the current detection circuit 7 is superposed onto the dispersion current Idac output from the DA conversion circuit 17 and supplied to the AD conversion circuit 8.

Further, the output of the logic circuit 19 is supplied to the arithmetic circuit 18 connected to the output terminal d of the AD conversion circuit 8. The logic circuit 19 is supplied with the test signal Test_en and the offset value Offset. When the test signal Test_en indicates the test state, the logic circuit 19 becomes conductive and supplies the offset value Offset supplied to the arithmetic circuit 18. The arithmetic circuit 18 subtracts the offset value Offset from the output signal supplied from the AD conversion circuit 8, and supplies the result of the subtraction to the correction circuit 9 from the output terminal e.

Although not particularly limited, the offset value Offset is determined in advance and stored in the control circuit CNT (FIG. 13) of the tester TST (FIG. 13). In Step S3 (FIG. 12A) which is the testing step, the control circuit CNT supplies the offset value Offset to the control circuit 22 of the semiconductor device 1 via an external terminal TS_T4 of the tester TST and the external terminal T4 of the semiconductor device 1.

### <<Superposition of Dispersion Current>>

### <<<Example of Current Detection Circuit 7>>>

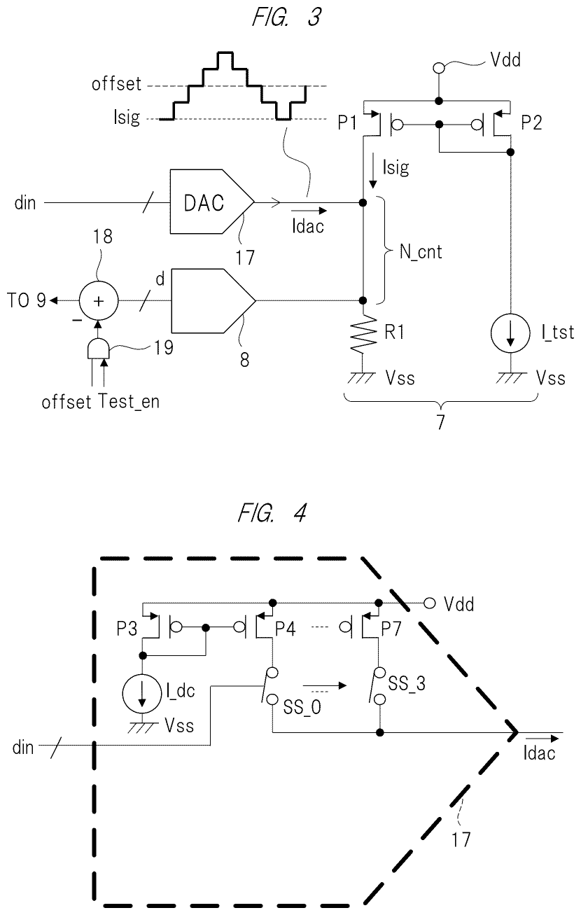

FIG. 3 is a block diagram for illustrating the superposition of dispersion current according to the first embodiment. FIG. 3 illustrates a portion corresponding to the AD conversion circuit 8, the DA conversion circuit 17, the logic circuit 19, the arithmetic circuit 18 and the current detection circuit 7 illustrated in FIG. 1. In FIG. 3, in particular, a portion corresponding to the current detection circuit 7 is illustrated in detail. FIG. 3 illustrates a state in which the test current I_tst is supplied from the tester TST (FIG. 13) to the current detection circuit 7 during testing. The test current I_tst is illustrated as a current source in FIG. 3 for ease of illustration.

The current detection circuit 7 includes a P-type MOS transistor P1 and a resistor element R1, which are connected in series between the power supply voltage Vdd and the ground voltage Vss, and a P-type MOS transistor P2 and a current source I_tst, which are connected in series between the power supply voltage Vdd and the ground voltage Vss. A gate electrode of the P-type MOS transistor P2 is connected to a drain terminal of the P-type MOS transistor P2 and a gate of the P-type MOS transistor P1, forming a current mirror circuit with the P-type MOS transistors P1 and P2.

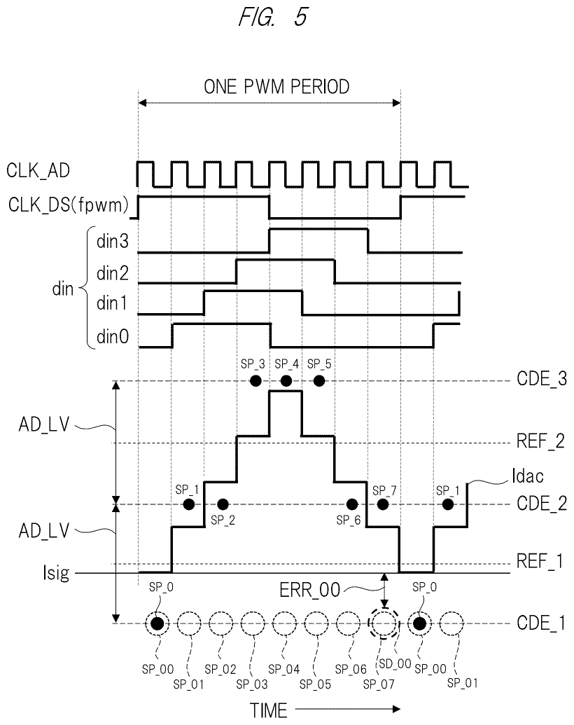

The output of the DA conversion circuit 17 and the input of the AD conversion circuit 8 are connected to a connection node N_cnt between the drain terminal of the P-type MOS transistor P1 and the resistor element R1. Next, an example of the DA conversion circuit 17 will be described using FIG. 4. The DA conversion circuit 17 forms the triangular waveform dispersion current Idac. Accordingly, the triangular waveform dispersion current Idac, formed by the DA conversion circuit 17, is superposed onto the detection current Isig, which is proportional to the test current I_tst, and flows through the resistor element R1. As a result, in the resistor element R1, a voltage, that corresponds to the detection current Isig on which the dispersion current Idac is superposed and that varies in accordance with the periodic changes in the dispersion current Idac, is generated. The voltage is converted into a digital output signal by the AD conversion circuit 8. The connection node N_cnt can be regarded as a superposition circuit that superposes the dispersion current Idac on the detection current Isig.

### <<<<One Example of DA Conversion Circuit 17>>>

FIG. 4 is a circuit diagram illustrating an example of the DA conversion circuit according to the first embodiment. FIG. 4 illustrates a case in which the decoder 16 illustrated in FIG. 1 supplies 4-bit digital signals din0 to din3 as the output signal din to the DA conversion circuit 17.

The DA conversion circuit 17 includes P-type MOS transistors P3 to P7, a constant current source I_dc, and four switches SS_0 to SS_3 that are switch-controlled by the 4-bit digital signals from the decoder 16. The source of the P-type MOS transistor P3 is connected to the power supply voltage Vdd, and the drain is connected to the ground voltage Vss via the constant current source I_dc and to the gates of the P-type MOS transistors P4 to P7. Also, the sources of the P-type MOS transistors P4 to P7 are connected to the supply voltage Vdd. Accordingly, a current mirror circuit is formed with the P-type MOS transistors P3 to P7. In the first embodiment, the P-type MOS transistors P4 to P7 are of the same size, and the currents that flow when the corresponding switches SS_0 to SS_3 are turned on are of the same value.

The decoder 16 according to the first embodiment outputs, as the output signal din, a signal that sequentially transitions to a high level from digital signals din0 to din3, and after all digital signals reach the high level, transitions to a low level from digital signals din3 to din0. As a result, the dispersion current Idac that varies in a triangular waveform as illustrated in FIG. 3 is formed.

As illustrated in FIG. 3, the dispersion current Idac is a current that varies in a triangular waveform above a reference value with the detection current Isig being the reference value. To obtain the averaging effect, it is desirable that the current input to the AD conversion circuit 8 varies above and below the detection current Isig as the center. Therefore, in the dispersion current Idac, the intermediate value between the reference value and, for example, the maximum value of the dispersion current Idac, that is, the center value between the peaks of the dispersion current Idac, is set as the offset value Offset.

During testing, the logic circuit 19 is turned to conductive by the test signal Test_en, the offset value Offset is subtracted from the output signal of the AD conversion circuit 8 by the arithmetic circuit 18, and the subtraction result is supplied to the tester TST via the correction circuit 9 and the averaging circuit 11. In this manner, a code corresponding to a triangular wave is generated digitally, converted to analog by the DA conversion circuit 17, and superposed on the detection current Isig, so that an increase in the occupation area can be suppressed. Moreover, the offset is removed by digital calculation, which leads to simplicity. Furthermore, offset removal can be performed only when necessary, such as during testing.

### <<Schematic Operation Waveforms During Testing>>

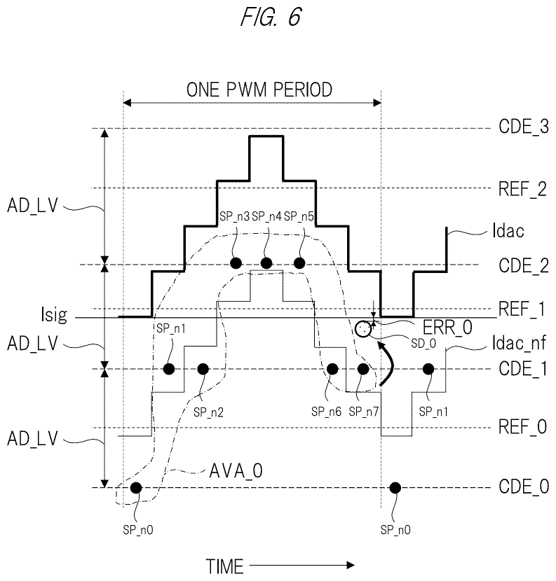

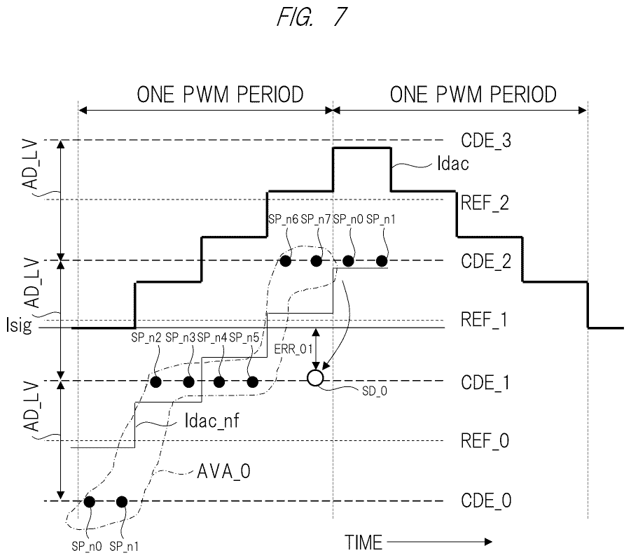

Next, the operation during testing will be described using schematic waveforms. FIGS. 5 and 6 are schematic waveform diagrams for illustrating the operation during testing of the semiconductor device according to the first embodiment.

Hereinafter, the operation during testing will be described with reference to FIG. 1 and FIGS. 4 to 6. For ease of understanding, as mentioned above, FIGS. 5 and 6 are schematic waveform diagrams.

In the following description, it is assumed that the frequency of the clock signal CLK_DS is set to ⅛ the frequency of the clock signal CLK_AD, as illustrated as an example in FIG. 1. Accordingly, as illustrated in FIG. 5, eight periods of the clock signal CLK_AD are generated in one period of the clock signal CLK_DS (one PWM period).

When the clock signal CLK_AD varies, the decoder 16 supplies the output signal din (din0 to din3) as illustrated in FIG. 5 to the DA conversion circuit 17 illustrated in FIG. 4. Accordingly, with the detection current Isig from the current detection circuit 7 being the reference value, the DA conversion circuit 17 outputs the dispersion current Idac that varies in a triangular waveform in one PWM period. That is, during a period of ½ the PWM period, the dispersion current Idac rises in a stepped manner with the detection current Isig being the base, reaches the maximum value (peak value), and then falls in a stepped manner from the maximum value toward the base (Isig) during the remaining period.

In FIG. 5, SP_0 to SP_7 indicate sampling timing of the AD conversion circuit 8 and values of output codes of the AD conversion circuit 8, similar to the black circles SP described for the output terminal d in FIG. 2.

In FIG. 5, CDE_1 to CDE_3 indicate output codes of the AD conversion circuit 8. Here, it is assumed that the corresponding analog values increase from the output codes CDE_1 to CDE_3. The adjacent output codes (for example, CDE_2 and CDE_3) correspond to a single level AD_LV of the AD conversion circuit 8. With, for example, the central values REF_1, REF_2 of each of the single levels AD_LV being a threshold, the AD conversion circuit 8 outputs either the output code above the threshold or the output code below the threshold depending on whether or not the value acquired at the sampling time exceeds the threshold. That is, the AD conversion circuit 8 sequentially converts the analog values acquired at the sampling timing in the order of the black circles SP_0 to SP_7 into output codes, which are digital signals, and the output codes to be converted are determined by comparing the acquired analog value with the threshold value.

For example, at the sampling time of the black circle (•) SP_0, the value of the detection current Isig superposed with the dispersion current Idac is lower than a threshold value REF_1 between the output codes CDE_1 and CDE_2, and therefore the AD conversion circuit 8 outputs the output code CDE_1, which is lower than the threshold value REF_1, as the output code of the black circle SP_0.

Also, for example, at the sampling time of the black circle (•) SP_1, the value of the detection current Isig superposed with the dispersion current Idac exceeds the threshold value REF_1 between the output codes CDE_1 and CDE_2, and therefore the AD conversion circuit 8 outputs the output code CDE_2, which is above the threshold value REF_1, as the output code of the black circle SP_1. Further, at the sampling time of the black circle (•) SP_2, the value of the detection current Isig superposed with the dispersion current Idac is lower than the threshold value REF_2 between the output codes CDE_2 and CDE_3, and therefore the AD conversion circuit 8 outputs the output code CDE_2, which is lower than the threshold value REF_2, as the output code of the black circle SP_2.

Similarly hereinafter, the AD conversion circuit 8 determines the output code to be output depending on whether or not the value of the detection current Isig superposed with the dispersion current Idac exceeds the threshold value. As a result, the output code represented by the output signal output from the AD conversion circuit 8 varies even if the value of the detection current Isig does not vary.

FIG. 5 illustrates a state in which the dispersion current Idac varies with the detection current Isig being the reference (base). That is, a state is illustrated in which the dispersion current Idac having the offset value Offset is superposed on the detection current Isig. In the first embodiment, as illustrated in FIG. 1, the arithmetic circuit 18 subtracts the offset value Offset from the output signal from the AD conversion circuit 8, and the digital signal from which the offset has been removed is supplied to the averaging circuit 11 via the correction circuit 9. The bit string of the digital signal representing the offset value Offset corresponds to the least significant bit in the output signal output from the AD conversion circuit 8. Therefore, even if the offset value Offset is subtracted from the output signal of the AD conversion circuit 8 by the arithmetic circuit 18 after conversion by the AD conversion circuit 8, there is little effect on the detection current Isig.

Next, the state in which the offset value Offset has been removed and averaging will be described with reference to FIG. 6.

FIG. 6 is similar to FIG. 5. The main differences are in that, in FIG. 6, the clock signals CLK_AD, CLK_DS and the output signal din of the decoder 16 are omitted, a dispersion current Idac_nf after the offset value Offset has been removed is illustrated by a thin solid line, an averaging area AVA_0 in which the averaging circuit 11 averages all at once is illustrated, a circle SD_0 indicating the sampling timing and output code is added, and a threshold value REF_0 and an output code CDE_0 are explicitly illustrated.

By removing the offset value Offset, the dispersion current Idac shifts downward, that is, to a lower value side, as illustrated in FIG. 6, and becomes the dispersion current Idac_nf. Since the dispersion current Idac_nf has shifted to the lower value side, the output code CDE_0 which is smaller than the output code CDE_1 and the threshold value REF_0 for determination are explicitly illustrated. By removing the offset value Offset, the black circles SP_0 to SP_7 indicating the sampling timing and output codes illustrated in FIG. 5 also shift to the lower value side, becoming SP_n0 to SP_n7, as illustrated in FIG. 6.

The averaging circuit 11 averages the output codes of black circles SP_n0 to SP_n7 included in one PWM period (averaging area) to obtain an average value. The obtained average value is sampled by the downsampling circuit 12. In FIG. 6, the output code obtained by sampling by the downsampling circuit 12 (the code represented by the output of the downsampling circuit 12) is indicated by a circle SD_0.

### <<<Errors>>>

In FIG. 5, dashed circles SP_00 to SP_07 indicate sampling times and output codes when only the detection current Isig is converted by the AD conversion circuit 8 without superposing the dispersion current Idac on the detection current Isig. As described with reference to FIG. 13, during testing, a test current I_tst, which is a predetermined fixed current, is applied to a terminal T1, and therefore the detection current Isig has a constant value. In the example of FIG. 5, since the value of the detection signal Isig is lower than the threshold value REF_1, the AD conversion circuit 8 outputs the output code CDE_1 as the output code at the sampling timings of the dashed circles SP_00 to SP_07. That is, the AD conversion circuit 8 outputs an output code of the same value (CDE_1). Therefore, even if the averaging circuit averages the values, the values will be the same. In FIG. 5, a dashed circle SD_00 indicates the sampling timing of the downsampling circuit 12 and the output code output by the downsampling circuit 12. Since the value does not vary even when averaging is performed by the averaging circuit 11, the output code output by the downsampling circuit 12 becomes CDE_1, as illustrated in the dashed circle SD_00.

In the test, the output code of the dashed circle SD_00 is output as the detection current Idet to the tester TST via the external terminal T2. As illustrated in FIG. 5, the difference between the dashed circle SD_00 (output code) and the detection current Isig is an error ERR_00, and this error ERR_00 is transmitted to the tester TST.

Whereas, when the dispersion current Idac is superposed on the detection current Isig as in the first embodiment, the output codes of the black circles SP_n0 to SP_n7 included in the averaging area AVA_0 are dispersed, as illustrated in FIG. 6. The averaging circuit 11 determines the average value of the output codes (black circles SP_n0 to SP_n7) included in the averaging area AVA_0, and the downsampling circuit 12 determines the output code (circle SD_0) that corresponds to the average value. The difference between the obtained output code of the circle SD_0 and the detection current Isig is the error ERR_0. As can be understood from FIGS. 5 and 6, according to the first embodiment, the error in the AD conversion circuit 8 can be reduced.

That is, a measurement value with a reduced error can be obtained during testing while suppressing a cost increase.

### Comparative Example

In FIGS. 5 and 6, the example has been described in which one period of PWM (=one period of the clock signal CLK_DS) and one period of the dispersion current Idac coincide with each other. As a result, in one PWM period corresponding to one downsampling period, the output code of one period of the dispersion current Idac can be superposed on the detection current Isig, thereby improving the averaging effect and reducing the error as illustrated in FIG. 6.

Whereas, for example, if one period of the dispersion current Idac corresponds to a plurality of periods of the PWM, the dispersion of the output code of the dispersion current Idac will span a plurality of periods of the PWM. In other words, in one PWM period, the output code of the dispersion current Idac becomes biased, and the effect of error reduction decreases.

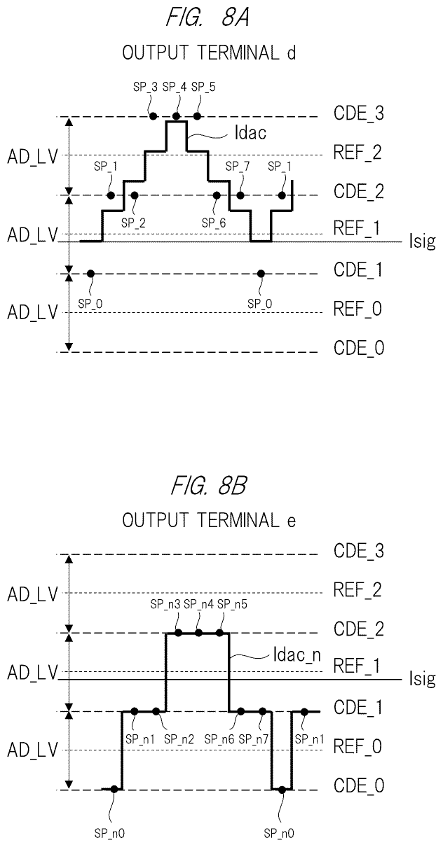

FIG. 7 is a waveform diagram illustrating a comparative example according to the first embodiment. FIG. 7 is similar to FIG. 6. The main difference is in that, in FIG. 7, as illustrated in the dispersion current Idac, one period of the dispersion current Idac corresponds to two periods of the PWM.

Further, in FIG. 7, it differs from FIG. 6 in that, the AD conversion at two adjacent sampling timings results in output codes of the same value being output from the AD conversion circuit, which is also a difference between FIGS. 6 and 7. For example, taking two adjacent black circles SP_n0 and SP_n1 as an example, one period of the dispersion current Idac (dispersion current Idac_nf after offset removal) is twice as long as that in FIG. 6, accordingly, the AD conversion circuit 8 samples the same value of dispersion current Idac_nf at the sampling timings of both the black circles SP_n0 and SP_n1. In the example of FIG. 7, since the value acquired at the sampling timing is lower than the threshold value REF_0, the values of the output codes indicated by the black circles SP_n0 and SP_n1 are both CDE_0. Similarly, with respect to the output codes indicated by the other black circles SP_n2 to SP_n7, the values of the output codes indicated by two adjacent black circles are the same.

As can be understood from the black circles SP_n0 to SP_n7 illustrated in FIG. 7, during one PWM period, the output code of the dispersion current Idac_nf (Idac) just increases (or decreases) and becomes biased. As a result, the output code of the downsampling circuit obtained by averaging the output codes included in the averaging area AVA_0, and downsampled thereof has the value of the output code CDE_1, as illustrated in the circle SD_0. As a result, the error, which is the difference between the detection current Isig and the output code CDE_1 indicated by the circle SD_0, becomes large, and the reduction effect decreases.

To enhance the reduction effect, it is required that the period of the dispersion current Idac is set to an integer fraction of one PWM period.

### <<Schematic Waveforms During Testing>>

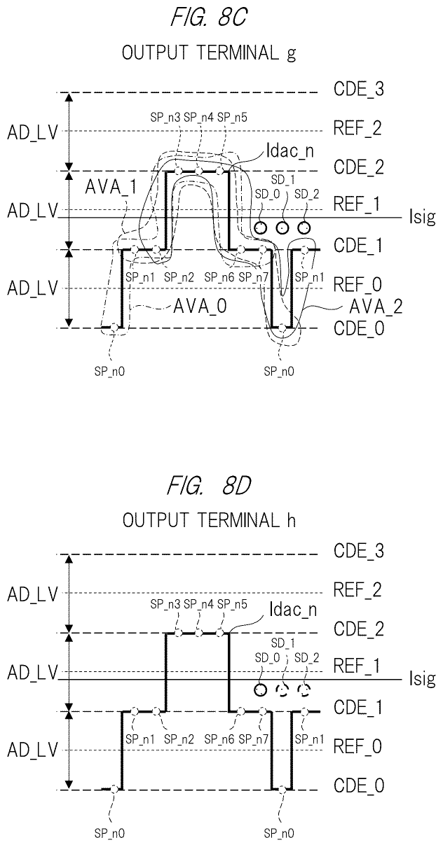

FIGS. 8A to 8D are waveform diagrams illustrating the operation of the semiconductor device according to the first embodiment during testing. FIG. 8A illustrates a waveform at the output terminal d of the AD conversion circuit 8 illustrated in FIG. 1, and FIG. 8B illustrates a waveform at the output terminal e of the arithmetic circuit 18 illustrated in FIG. 1. Also, FIG. 8C illustrates a waveform at the output terminal g of the averaging circuit 11 illustrated in FIG. 1, and FIG. 8D illustrates a waveform at the output terminal h of the downsampling circuit 12 illustrated in FIG. 1.

Each of FIGS. 8A to 8D is similar to FIGS. 5 and 6. That is, FIG. 8A illustrates the detection current Isig and the dispersion current Idac illustrated in FIG. 5, and further illustrates black circles SP_1 to SP_7 indicating the sampling timings and the values of the output codes. The dispersion current Idac is superposed on the detection current Isig, and the detection current on which the dispersion current is superposed is sampled at a timing of a black circle SP illustrated in FIG. 8A and converted into a value of an output code indicated by the black circle SP.

The arithmetic circuit 18 subtracts the offset value from the digital signal at the output terminal d. As a result, as illustrated in FIG. 8B, the black circles SP_n0 to SP_n7 indicating the output code values of the dispersion current shift downward. In FIG. 8B, the waveform Idac n is formed by connecting the output codes indicated by the black circles SP_n0 to SP_n7, and indicates the waveform of the dispersion current generated by removing the offset value after AD conversion.

The detection current on which the dispersion current Idac n is superposed illustrated in FIG. 8B is averaged by the averaging circuit 11 via the correction circuit 9. In FIG. 8C, AVA_0 is an averaging area including the black circles SP_n0 to SP_n7. Averaging of the output codes indicated by the black circles SP_n0 to SP_n7 included in the averaging area AVA_0 is executed by the averaging circuit 11 at a first timing. An average value obtained by averaging at the first timing is indicated by a circle SD_0.

In addition, in FIG. 8C, AVA 1 is an averaging area including black circles SP_n1 to SP_n0. Averaging of the output codes indicated by the black circles SP_n1 to SP_n0 included in the averaging area AVA 1 is executed by the averaging circuit 11 at a second timing following the first timing, and an average value obtained by the execution is indicated by a circle SD_1. Further, in FIG. 8C, AVA_2 is an averaging area including the black circles SP_n2 to SP_n1. Averaging of the output codes indicated by the black circles SP_n2 to SP_n1 included in the averaging area AVA_2 is executed by the averaging circuit 11 at a third timing following the second timing, and an average value obtained by the execution is indicated by a circle SD_2.

As a result of sampling by the downsampling circuit 12, the average value (value indicated by the circle SD_0) obtained at the first timing is acquired by the averaging circuit 11, as illustrated in FIG. 8D. The obtained average value is supplied to the tester TST (FIG. 13) via the switch 21 and the external terminal T2. Thereafter, the average value acquired at the second timing (dashed circle SD_1) and the average value acquired at the third timing (dashed circle SD_2) are supplied to the tester TST in that order.

The tester TST generates the correction data C_data using the supplied average values or the like.

### Second Embodiment

In the first embodiment, as illustrated in FIG. 1, the output of the counter 14 for generating the PWM frequency is used to generate the digital output signal din for generating the dispersion current Idac. Whereas, in the second embodiment, a counter that generates the output signal din is newly added.

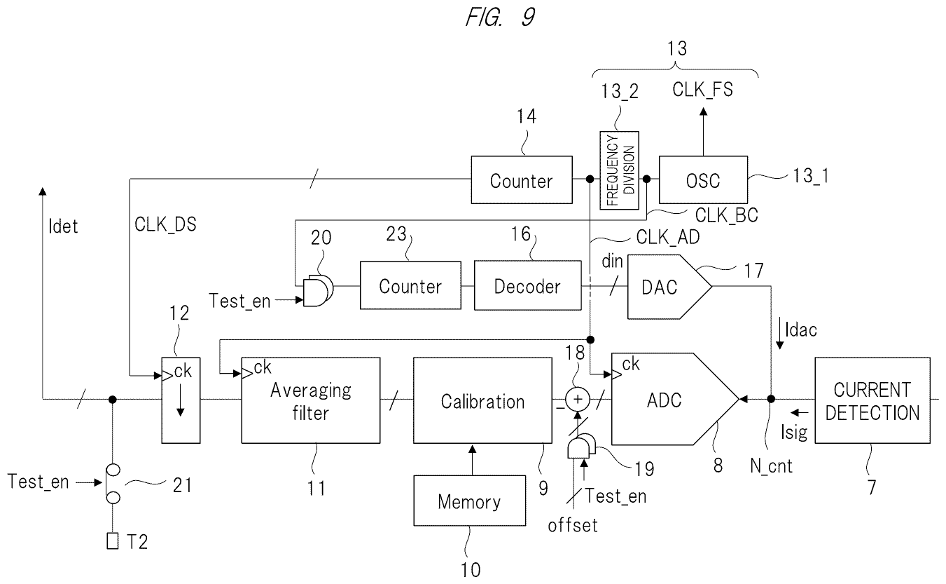

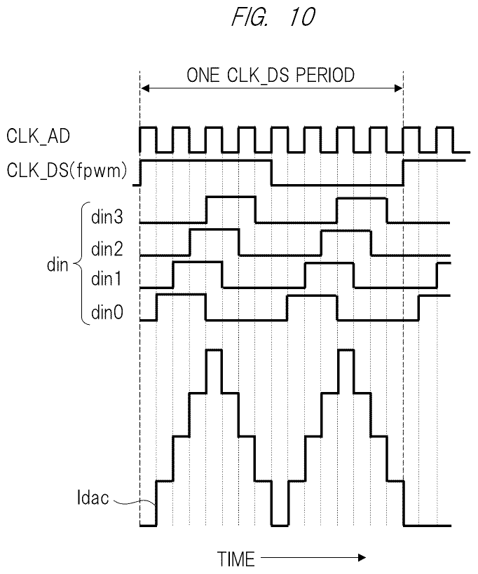

FIG. 9 is a block diagram for illustrating a semiconductor device according to the second embodiment. FIG. 10 is a waveform diagram illustrating an operation of the semiconductor device according to the second embodiment. FIG. 9 illustrates only parts necessary for illustrating the second embodiment, among the circuit blocks illustrated in FIG. 1. The parts illustrated in FIG. 1 but not illustrated in FIG. 9 are the same as those in FIG. 1.

The frequency generator 13 illustrated in FIG. 1 is configured with an oscillation circuit (OSC) 13_1 and a frequency divider circuit (frequency divider) 13_2 in FIG. 1. The oscillation circuit 13_1 generates the above-mentioned clock signal CLK_FS and a clock signal CLK_BC. The clock signal CLK_BC is divided by a frequency divider circuit 13_2 and supplied to the counter 14. In FIG. 9, the output of the counter 14 is supplied to a clock terminal ck of the downsampling circuit 12 as a clock signal CLK_DS. Naturally, similarly to FIG. 1, the output of the counter 14 may be supplied to the PWM frequency generation circuit 15, and the PWM frequency generation circuit 15 may generate the clock signal CLK_DS.

In the second embodiment, a counter 23 is added. The counter 23 receives the clock signal CLK_BC generated by the oscillation circuit 13_1 via a logic circuit 20. Accordingly, when a test is instructed by the test signal Test_en, the logic circuit 20 becomes conductive and the clock signal CLK_BC is supplied to the counter 23. As a result, during testing, the counter 23 counts the clock signal CLK_BC and supplies the count value to the decoder 16. As in the first embodiment, the decoder 16 decodes the count value to generate a digital output signal din. The output signal din is supplied to the DA conversion circuit 17, and the DA conversion circuit 17 generates the dispersion current Idac.

FIG. 10 illustrates waveforms of the clock signals CLK_AD, CLK_DS, the output signal din, and the dispersion current Idac illustrated in FIG. 9. By providing a dedicated counter 23 to generate the dispersion current Idac, it becomes possible to make the output signal din have two periods in one period of the clock signal CLK_DS, as illustrated in FIG. 10, and to generate the dispersion current Idac having a triangular waveform twice. That is, it is possible to arbitrarily set the period of the dispersion current Idac in one period of the clock signal CLK_DS.

When a sufficient averaging effect cannot be obtained with a single period of the dispersion current Idac in one PWM period as illustrated in FIG. 5, then it is possible to increase the number of dispersion periods and improve the averaging effect by increasing the period of the dispersion current Idac as in the second embodiment.

### Third Embodiment

In the first embodiment, the example in which the offset is removed digitally has been illustrated, and in the third embodiment, an example in which the offset is removed analogically will be illustrated.

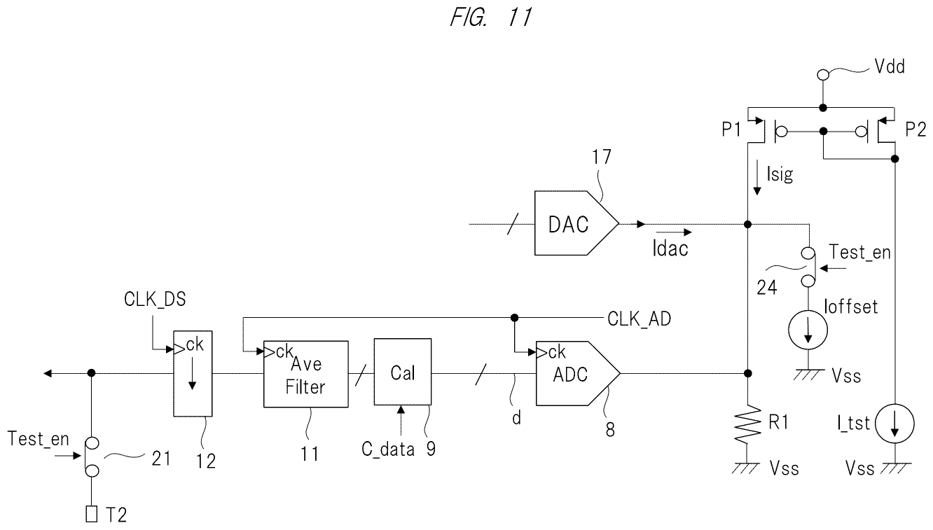

FIG. 11 is a block diagram for explaining a semiconductor device according to the third embodiment. FIG. 11 is similar to FIG. 3. The main differences are in that FIG. 11 illustrates a correction circuit 9, an averaging circuit 11, and a downsampling circuit 12 connected to the output terminal d of the AD conversion circuit 8, and illustrates a configuration for removing an offset analogically.

The configuration for removing the offset analogically is configured by a switch 24 and a constant current source Ioffset that are connected in series between the drain of a P-type MOS transistor P1 and the ground voltage Vss.

During testing, the switch 24 is brought into a conductive state by the test signal Test_en. The constant current source Ioffset is a current source that generates a constant current corresponding to the offset value Offset. When the switch 24 is brought into a conductive state, the offset current value included in the dispersion current Idac flows through the constant current source Ioffset. Accordingly, offset removal is performed during testing. Also, in the third embodiment, the arithmetic circuit 18 and the logic circuit 19 as illustrated in FIG. 1 are not necessary.

For example, when the process for manufacturing the semiconductor device 1 is not a fine process, a configuration for removing the offset analogically can suppress an increase in the occupation area. In this case, as described above, the arithmetic circuit 18 and the logic circuit 19 are also unnecessary, so that the increase in the occupation area can be further suppressed.

According to the first to third embodiments, since there is no need to mount elements (active elements, passive elements, etc.) for generating AC signals on the test board, it becomes possible to increase the number of semiconductor devices to be mounted during testing, and for example, the number of semiconductor devices measured simultaneously can be increased. Further, when generating an AC signal on a test board, delays may occur due to the generation of the AC signal and supply of the same to the semiconductor device, which may lengthen the test time. Whereas, in the embodiment, since the dispersion current corresponding to the AC signal is generated and superposed within the semiconductor device, it is possible to shorten the test time. Further, while a test design for generating an AC signal on the test board is required, in the first to third embodiments, it is sufficient to supply a fixed current to the semiconductor device during testing, allowing for a reduction in design man-hours related to testing.

Naturally, it is possible to provide a high-resolution semiconductor device without mounting a high-resolution AD conversion circuit on the semiconductor device; therefore, it is possible to reduce chip costs.

In the semiconductor device 1 illustrated in FIG. 1, the arithmetic circuit 18 can be regarded as an offset removing circuit that removes the offset value Offset. Additionally, it can be regarded that the current generation circuit is configured by the counter 14 or 23, the decoder 16, and the DA conversion circuit 17.

When regarded in this manner, in the testing step of Step S3 illustrated in FIG. 12, it can be considered that the following process is being executed.

The current generation circuit (DA conversion circuit 17) generates a second signal (dispersion current Idac) of the first period (1/Fpwm).

The second signal is superposed on the detection current (Isig: first signal) from the current detection circuit 7 at the first node (N_cnt in FIG. 1), generating a third signal.

The third signal is converted into a digital fourth signal by the AD conversion circuit 8, and the offset generated by superposing the second signal onto the first signal is removed from the fourth signal by the offset removing circuit, generating a fifth signal.

The generated fifth signal is averaged by an averaging filter (averaging circuit 11), generating a sixth signal. The generated sixth signal is downsampled by the downsampler (downsampling circuit 12), thinned out to data having a period that is an integer fraction of one period, generating a seventh signal.

This seventh signal is output from the semiconductor device 1 to the tester TST (in FIG. 13) during the test process, where correction data C_data is generated in the tester TST.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A semiconductor device comprising:
a first terminal; an oscillation circuit that generates a first clock signal and a second clock signal having a frequency that is an integer fraction of the first clock signal;
an AD conversion circuit that oversamples a detection current corresponding to a current flowing through the first terminal in accordance with the first clock signal and converts the detection current into a digital signal;
a correction circuit that corrects the digital signal obtained by the AD conversion circuit based on a correction data stored in a memory circuit and outputs the digital signal;
an averaging circuit that operates in accordance with the first clock signal and averages the digital signal output from the correction circuit;
a sampling circuit that downsamples the digital signal averaged by the averaging circuit in accordance with the second clock signal;
a current generation circuit that generates a current based on an output of the sampling circuit and target current data and supplies the current to the first terminal; and
a superposition circuit that superposes a dispersion current on the detection current when generating the correction data,
wherein the correction data is generated based on an output of the sampling circuit when the dispersion current is superposed on the detection current, and is stored in the memory circuit.

2. The semiconductor device according to claim 1, further comprising:
a second terminal that outputs an output of the sampling circuit when the dispersion current is superposed on the detection current to an outside of the semiconductor device; and
a third terminal, which is provided outside the semiconductor device, and to which the correction data generated based on the output of the sampling circuit output from the second terminal is supplied,
wherein the correction data supplied to the third terminal is written into the memory circuit.

3. The semiconductor device according to claim 2, further comprising
a DA conversion circuit that generates the dispersion current,
wherein the DA conversion circuit generates the dispersion current which varies periodically.

4. The semiconductor device according to claim 3, further comprising:
a current detection circuit connected to the first terminal and that outputs a detection current corresponding to a current flowing through the first terminal; and
an arithmetic circuit connected between the AD conversion circuit and the correction circuit,
wherein, when generating the correction data, a predetermined current is supplied to the first terminal, the current detection circuit outputs the detection current corresponding to the predetermined current, a digital signal corresponding to the detection current on which the dispersion current is superposed and a digital signal corresponding to an offset caused by superposing the dispersion current are supplied to the arithmetic circuit, and the arithmetic circuit subtracts the digital signal corresponding to the offset from the digital signal corresponding to the detection current on which the dispersion current is superposed.

5. A method of manufacturing a semiconductor device, comprising steps of:
(a) preparing a semiconductor substrate;
(b) forming a plurality of circuits including a first circuit that outputs a first signal corresponding to target current data via a first terminal on a surface of the semiconductor substrate; and
(c) correcting the first circuit,
wherein the first circuit includes
a current detection circuit connected to the first terminal,
an AD conversion circuit connected to the current detection circuit,
a correction circuit connected to the AD conversion circuit,
an averaging filter connected to the correction circuit, and
a downsampler connected to the averaging filter,
wherein the plurality of circuit further includes
an offset removing circuit connected to the AD conversion circuit, and
a current generation circuit connected to a first node that connects the current detection circuit and the AD converting circuit, and
wherein the step of (c) includes steps of
(c1) superposing a second signal having a first period generated by the current generation circuit on the first signal at the first node to generate a third signal,
(c2), after the step of (c1), converting the third signal, which is an analog signal, into a digital signal in the AD conversion circuit to generate a fourth signal,
(c3), after the step of (c2), removing an offset caused by superposing the second signal included in the fourth signal on the first signal using the offset removing circuit to generate a fifth signal,
(c4), after step of (c3), averaging the fifth signal using the averaging filter to generate a sixth signal,
(c5), after the step of (c4), thinning out data at a period that is an integer fraction of the first period using the downsampler to generate a seventh signal, and
(c6), after the step of (c5), outputting the seventh signal to outside.

6. The method of manufacturing the semiconductor device according to claim 5,
wherein the second signal is a signal having a triangular waveform.

7. The method of manufacturing the semiconductor device according to claim 6,
wherein the current generation circuit includes
a counter,
a decoder connected to the counter, and
a DA conversion circuit connected to the decoder, and
wherein the DA conversion circuit includes a current mirror circuit including a switch that is turned On/Off by an output of the decoder.

8. The method of manufacturing the semiconductor device according to claim 7,
wherein the counter is the same as a counter used to obtain a period that is an integer fraction of the first period.

9. The method of manufacturing the semiconductor device according to claim 5,
wherein the seventh signal output in the step of (c6) is supplied to a tester provided externally, and the tester generates correction data to be used in the correction circuit.

10. The method of manufacturing the semiconductor device according to claim 9,
wherein the plurality of circuits include a memory circuit connected to the correction circuit, and
wherein the memory circuit stores the correction data generated by the tester, and the correction circuit performs correction based on the correction data stored in the memory circuit.
